(19) United States
(12) Patent Application Publication
(10) Pub. No.: US 2014/0167134 A1
(43) Pub. Date: Jun. 19, 2014

(54) SELF-ALIGNED VERTICAL NONVOLATILE SEMICONDUCTOR MEMORY DEVICE

(71) Applicants: Pengfei Wang, Shanghai (CN); Xi Lin, Shanghai (CN); Qingqing Sun, Shanghai (CN); Wei Zhang, Shanghai (CN)

(72) Inventors: Pengfei Wang, Shanghai (CN); Xi Lin, Shanghai (CN); Qingqing Sun, Shanghai (CN); Wei Zhang, Shanghai (CN)

(73) Assignee: FUDAN UNIVERSITY, Shanghai (CN)

(21) Appl. No.: 13/514,032

(22) PCT Filed: Feb. 2, 2012
(86) PCT No.: PCT/CN12/00137

§ 371 Date: Jun. 5, 2012

(30) Foreign Application Priority Data
Aug. 25, 2011 (CN) 201110246283.4

(51) Int. Cl. H01L 27/115

(52) U.S. Cl. CPC H01L 27/11563
USPC 257/324

(57) ABSTRACT

The present invention belongs to the technical field of semiconductor memory devices and specifically relates to a self-aligned vertical nonvolatile semiconductor memory device, Including: a semiconductor substrate, a drain region of a first doping type, two source regions of a second doping type, a stacked gate used to capture electrons; wherein the drain region, the two source regions and the stacked gate form two tunneling field effect transistors (TFETs) sharing one gate and one drain, the drain region current of each of the TFET is affected by the quantity and distribution of the charges in the stacked gate used to capture electrons, the drain is buried in the semiconductor substrate, the source regions above the drain region are separated from the drain through a channel and separated form each other through a region of the first doping type. The semiconductor memory device of the present invention features small unit area and simple manufacturing process. The memory chip using the present invention is of low manufacturing cost and high storage density.

### BACKGROUND OF THE INVENTION

1. Technical Field

The present invention belongs to the technical field of semiconductor memory devices and specifically relates to a self-aligned vertical nonvolatile semiconductor memory device.

2. Description of Related Art

Semiconductor memory has been widely used in various fields such as industrial controls and consumer electronics. The basic requirements for the memory chip include high integration density, low power consumption, and high speed. Generally, there are two ways to improve the storage capacity of memory in the same chip area, wherein one is to reduce the feature size of the storage unit in scale, the other is to optimize the device structure or use a new-type device.

Since both the electric erasable programmable read-only memory (EEPROM [1]) and the nitrided read-only memory (Nitrided ROM [2]) are based on the device structure designed by MOSFET, when the feature size of these storage units are reduced in scale, they will be restrained by the short channel effect. Therefore, a new-type of device capable of restraining the short channel effect are preferred in this art for improving the chip storage capacity. In view of this, a self-aligned vertical tunneling field effect transistor read-only memory (TFET Read Only Memory), referred to as TROM, is put forward in the present invention. Due to the tunneling field effect transistor's (TFET's) capacity of suppressing the short channel effect, the TROM gate length can be reduced to 20 nm in scale with a small leakage current [3].

The storage density of the memory can be realized by optimizing the design. Take the planar Nitride ROM (NROM) device as an example, the device can store 2 bits of data with one storage unit, so its storage density is higher than that of EEPROM [2]. Similar to NROM, the self-aligned vertical TROM disclosed herein also has the storage capacity of 2 bits of data with one storage unit, so the density is correspondingly higher than that of EEPROM.

The storage unit array usually realizes mass storage through the matrix domain structure, and for the EEPROM flash memory, there are two kinds of matrixes: the NAND structure and the NOR structure. The source and drain contact pads are dispensable, so the storage density of the NAND is higher than that of the NOR structure. However, after using the self-aligned storage unit with a vertical structure, the NAND structure and the NOR structure can be combined together. The memory array disclosed by the present invention is of such combination of the two structures.

### BRIEF SUMMARY OF THE INVENTION

The present invention aims at providing a nonvolatile semiconductor memory device with high storage density and low power consumption, and the manufacturing method thereof.

The semiconductor memory device put forward by the present invention is a self-aligned vertical TFET nonvolatile semiconductor memory device and the structure is as shown in FIG. 1, including:

a semiconductor substrate;

a drain region of a first doping type;

two source regions of a second doping type; a channel region between the two source regions;

a stacked gate used to capture electrons, of which the structure includes a first dielectricdielectric, a second dielectric, a third dielectric and a metal gate in turn;

wherein, the drain region, the two source regions and the stacked gate form two TFETs sharing one gate and one drain; in addition, the drain region current of each TFET is affected by the quantity and distribution of the charges in the stacked gate used to capture electrons; the drain region is buried in the semiconductor substrate, the two source regions above the drain region are separated from the drain region through a channel and separated from each other by a doping region of the first doping type.

In the present invention, the substrate is an intrinsic semiconductor. Moreover, the substrate can be lightly doped.

In the present invention, the semiconductor substrate is a part of a silicon wafer; or a part of a silicon-germanium wafer or a stress silicon wafer.

A TROM array structure based on the semiconductor memory device above and the corresponding addressing modes are also provided in the present invention.

The present invention has the following advantages:

firstly, due to the use of reverse p-i-n structure in the design, as shown in FIG. 1, the TFET can restrain the short channel effect; as shown by simulations, the TROM devices can be further reduced in scale compared to the MOSFET, thus the storage density of the TROM storage unit can be improved by size reduction, while other MOSFETs based on ROM (such as NROM) can not realize this advantage;

secondly, the TFET, having extremely low sub-threshold leakage current, can enable the TROM with low waiting power consumption; besides, since the writing efficiency of the TROM is very high, as shown by simulations, the storage unit can conduct programming under a very low leakage current; this means that the programming power consumption is very low, so the TROM chip has great attraction for the low power consumption application field; by contrast, the NROM can only conduct programming with great leakage current, so its power consumption during programming is greater than the TROM put forward herein;

thirdly, the self-aligned vertical TROM (FIG. 1) put forward herein realizes the storage capacity of 2 bits of data per storage unit, namely doubling the TROM storage capacity, thus reducing the area required to store each bit of data; moreover, in this vertical design, the device drain is at the bottom of the substrate, and the chip area of the TROM is further saved compared to the conventional planar designs of the EEPROM and NROM (see FIG. 2);

fourthly, the TROM integrating the NOR structure and the NAND structure (see FIG. 3) enables each storage unit to be addressed rapidly and improves the addressing speed due to the tunnel current.

### BRIEF DESCRIPTION OF THE SEVERAL VIEWS OF THE DRAWINGS

FIG. 1 is the sectional view of the self-aligned vertical TFET.

FIG. 2 is the electric symbol of the self-aligned vertical TFET.

FIG. 3 is the sectional view of an embodiment that a TROM unit stores and addresses 2 bits of data.

FIG. 4 is the schematic diagram of an embodiment of the present invention: a 16-bit character string composed of 8 TROM units.

FIG. 5 is the schematic diagram of an embodiment of the present invention: an 8*8 memory array composed of TROM character strings. The array can store 16*8 bits of data.

FIG. 6 is the sectional view of a TROM array along the bit line direction.

FIG. 7 is the sectional view of a TROM array along the word line direction.

FIG. 8 is another sectional view of a TROM array along the word line direction.

FIG. 9 is the top view of an embodiment of a TROM array.

FIG. 10 is the top view of a self-aligned vertical TROM storage unit.

### DETAILED DESCRIPTION OF THE INVENTION

FIG. 1 is the schematic diagram of the structure of a TROM memory device. The device is manufactured on a semiconductor substrate 107, an n+ buried layer 108 is used as the drain, two p+ regions are used as the sources 101a, 101b, and between the two p+ source regions is a channel region 106. The structure above the channel region is a stacked gate structure, including a first dielectric 104, a second dielectric 103, a third dielectric 102 and a metal gate 105 in turn. Meanwhile, the adjacent sources 101a, 101b can be used as the source and drain of the traditional PMOS. Different from the existing MOSFET memories based on charge capture, in the TROM device, the information stored is determined by reading the current between the n+ buried region 108 and the p+ source (for example, 101a). Due to the partial charge capture effect, the tunneling current at the tunneling junctions 109, 110 will be affected by the partial charge captured in the second dielectric 103. This means that the tunneling current at the tunneling junctions 109, 110 varies with the change of the distribution and density of the charges in the second dielectric 103.

In order to illustrate the working principle of the TROM more clearly, divide the device shown in FIG. 1 into 2 memory devices of a left half and a right half capable of storing 1 bit of data respectively. The specific programming principle is as follows: when the gate is applied with a forward bias voltage, an n+ conductive channel 106 is formed under the first dielectric 104 and a p+/n+ Esaki-tunneling junction is formed at the tunneling junction 109. Connect the p+ region 101a on the left with the ground and simultaneously apply a forward bias (for example, of 2V) to the n+ region, then the electrons at the p+/n+ Esaki-tunneling junction will tunnel from the valence band to the conduction band. As a result of forward gate voltage, the hot electrons near part of the tunneling junctions will be injected to the first dielectric 104 and captured by the second dielectric 103, which is similar to the ONO stacked structure [6]. The electrons captured change the threshold voltage and the left-half device can be programmed. The memory device on the right can also be programmed by the same methods, thus storing 2 bits of information in a complete storage unit.

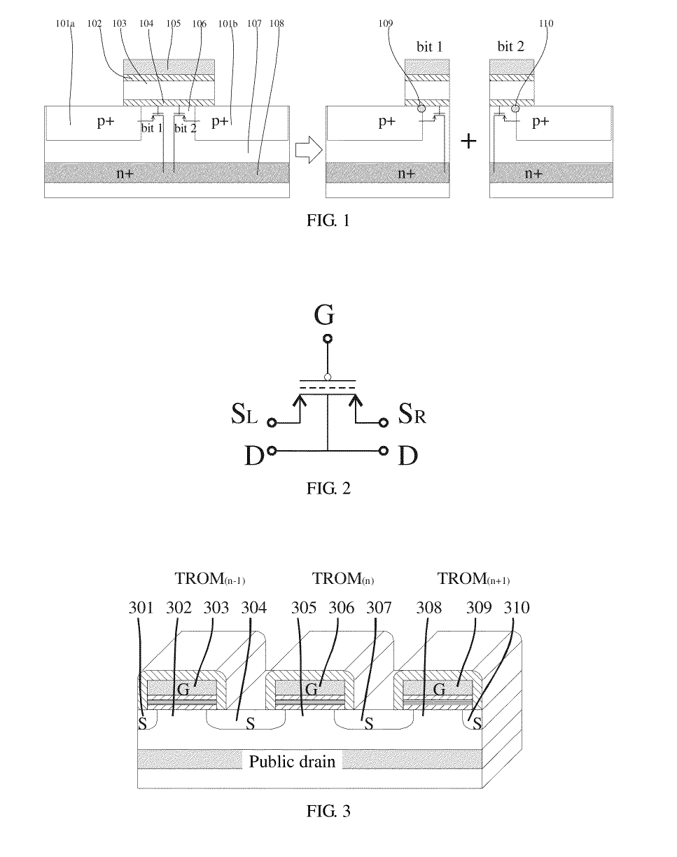

FIG. 2 shows the electric symbol of the self-aligned vertical TROM device. A TROM unit has 2 storage units. As described above, the storage unit on the left is composed of a source SL, a public drain D and a public gate G. Similarly, the storage unit on the right is composed of a source S_{R}, the public drain D and the public gate G. When the TFET unit on the left works, the electrons enter into the channel by tunneling from the S_{L} and are collected by the public drain D which is forward biased. For the TROM unit on the right, it can be done in the same manner.

The information erasing of the TROM device is realized by injecting hot holes into the channel. Forward-bias the p+ doped source 101a or 101b during erasing, and reverse-bias the gate 105, thus hot holes are injected into the gate dielectric and the original information stored is erased.

The description of how to access the 2 bits of information of a TROM will be given hereinafter. FIG. 3 shows 3 TROM units which have deposited a passivation layer on their gates, namely the TROM(n−1), TROM(n), and TROM(n+1).

During reading, the source 301 of the TROM (n−1) on the left is grounded, when the channel 302 of the TROM (n−1) is conductive, while other channels 305, 308 are cut off, the left part of the TFET (n) is selected, while the right part is not selected. Forward-bias the n+ doped public drain and the gate 306, and the electrons will flow from the p+ source region 304 to the drain. The current density is determined by the quantity and distribution of the charges on the dielectric 103. The right part of the TROM can be accessed in the same manner, thus the 2 bits of information stored can be accessed separately.

A TROM array structure based on the semiconductor above and the corresponding addressing modes are also provided in the present invention.

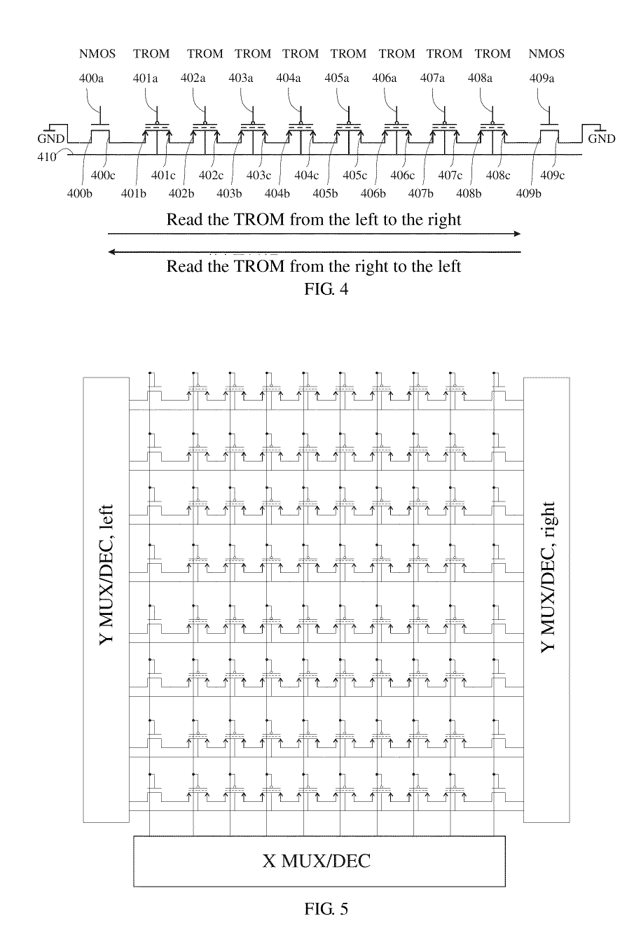

FIG. 4 shows an embodiment of a TROM memory string using 8 TROM units shown in FIG. 2 and FIG. 3. There is an nMOSFET on each end of the memory string, the corresponding source 400b and 409c are both grounded. The bit line 410 is forward biased.

As explained through FIG. 3, the 2 bits of information stored in the TROM will be accessed from two directions. When the gate 400a of the NMOS on the left is forward biased and the gate 409a of the NMOS on the right is grounded, the memory string is accessed from the left to the right, and vice versa. For instance, forward-bias the gate 400a, the ground voltage is transferred to the source 401b. The TROM unit composed of the source 401a, the drain 410 and the source 401b is activated and its information can be accessed. Then reverse the gate 401a to reverse bias and transfer the ground voltage to the source 402b of the next TROM unit. In this way, the TROM unit composed of the source 402a, the drain 410 and the source 402b is activated and its information can be accessed. By analog, all the left storage units of the TROM are accessed, during this period, the NMOS 409 on the right is cut off. The state of each TROM unit can be identified by monitoring the current on the bit line 410. When reading and writing the right part of the TROM, the NMOS transistor 400 on the left is cut off and the NMOS 409 on the right is conductive, thus the TROM will be accessed from the right to the left.

As shown in FIG. 4, the memory string with a storage capacity of 16 bits of information can be realized through 8 TROM units. Similarly, the memory string with a storage capacity of 2n bits can be realized by using n (n=1, 2, 3 . . . ) TROM units. In FIG. 4, the sources of the TROM are connected with each other through NAND gate structure, while the TROM units can be connected through NOR gate structure. With vertical structure, the NOR gate structure requires no extra area for contact connection. The combination of NAND gate structure and NOR gate structure not only assimilates the NAND gate structure's merits of rapid reading and high speed, but also possesses the NOR gate structure's advantage of rapid access of a single storage unit.

The unique characteristics of the TROM include: during working, the electrons of the p+ region are injected into the channel region and collected by the n+ public drain, and the current flows from the n+ drain to the p+ source. This means that the electrons are injected into the reverse-biased p-i-n diode. The monitoring of such injected electrons is similar to that of photo-induced electrons. As shown by the photo-detector in the high-frequency field, the non-equilibrium carriers of the reverse-biased p-i-n diode can be monitored rapidly, so the TROM memory has a high monitoring speed.

FIG. 5 shows a TROM memory array structure using 8 memory strings shown in FIG. 4. Wherein the word line connects the gates in the same row and is connected with the X selection/decoding circuit, and the bit line is connected with the source of the NMOS to the Y selection/decoding circuit. The peripheral circuit is used to realize the reading and writing of the memory array by conducting necessary operations to the X and Y selection/decoding circuit. The 8×8 TROM array shown in FIG. 5 has a storage capacity of 128 bits. Based on the same principle, the n×n TROM array can be designed. Since the power consumption of the TROM device is very low, the TROM array can perform parallel reading and writing, which is helpful in improving the working speed of the array.

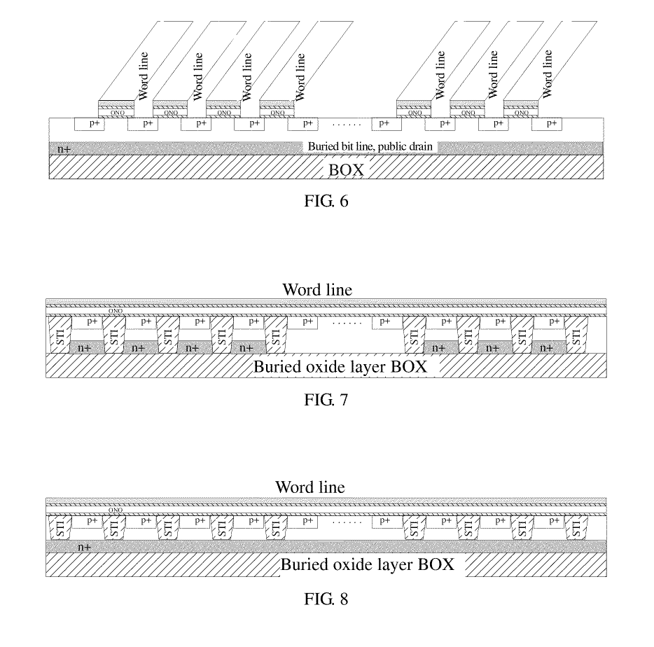

The embodiments of the manufacturing process of the TROM array disclosed by the present invention are described hereinafter. In terms of process, the non-contact TROM array is compatible with the standard CMOS process. FIG. 6 is the sectional view of a TROM array along the bit line direction. In the figures, the p+ regions are formed through self-aligned process, the n+ buried layer of the public drain is formed through ion implantation and the separation of the drain is realized through shallow trench isolation (STI). FIG. 7 shows the sectional view of the TROM array along the word line direction, wherein the public drain is isolated through STI. FIG. 8 is another sectional view along the word line direction, wherein the drain is a whole plate located under the STI.

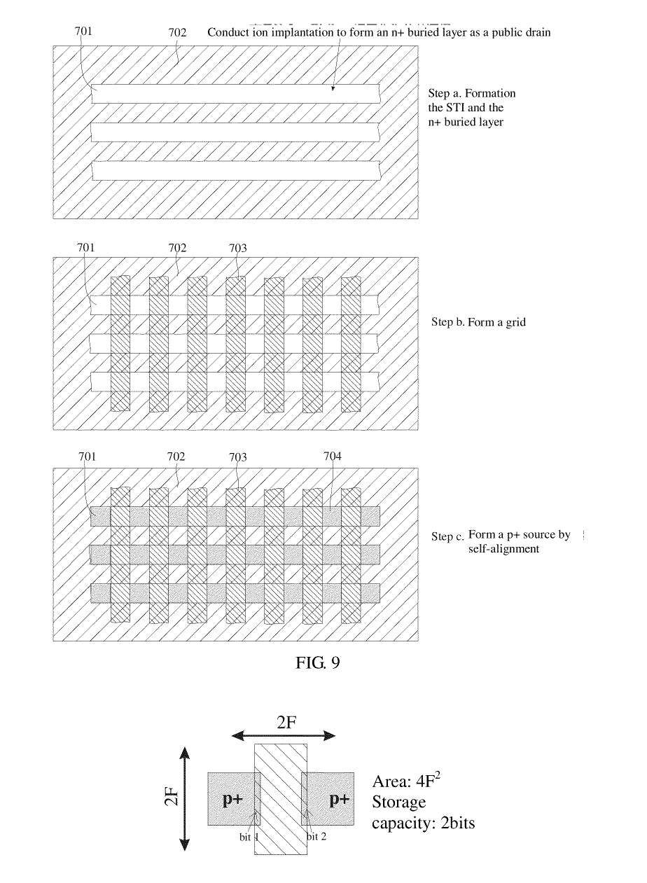

FIG. 9 is the top view of the manufacturing process of the TROM array.

The substrate 702 is of n-type doping or intrinsic state.

Firstly, form an STI, open an active region and manufacture an n+ buried layer 701 (ion implantation is preferred); at this time, the bit line is isolated by the STI;

next, deposit and patternize a stacked gate 703 as a word line;

next, form a self-aligned p+ block by injecting p-type impurities through ion implantation.

In addition, the threshold voltage of the PMOS can be adjusted through additional threshold adjustment process. The subsequent processes such as passivation, metallization and interconnection are the same as those of conventional VLSI process.

FIG. 10 shows the top view of a self-aligned vertical TORM unit which realizes the 2-bit storage through an area of 4 F² and the manufacturing of high-density memory array.

### INDUSTRIAL APPLICABILITY

The present invention has the following advantages:

firstly, due to the use of reverse p-i-n structure in the design, as shown in FIG. 1, the TFET can restrain the short channel effect; as shown by simulations, the TROM devices can be further reduced in scale compared to the MOSFET, thus the storage density of the TROM storage unit can be improved by size reduction, while other MOSFETs based on ROM (such as NROM) can not realize this advantage;

secondly, the TFET having extremely low sub-threshold leakage current can enable the TROM with low waiting power consumption; besides, since the writing efficiency of the TROM is very high, as shown by simulations, the storage unit can conduct programming under a very low leakage current; this means that the programming power consumption is very low, so the TROM chip has great attraction for the low power consumption application field; by contrast, the NROM can only conduct programming with great leakage current, so its power consumption during programming is greater than the TROM put forward herein;

thirdly, the self-aligned vertical TROM (FIG. 1) put forward herein realizes the storage capacity of 2 bits of data per storage unit, namely doubling the TROM storage capacity, thus reducing the area required to store each bit of data; moreover, in this vertical design, the device drain is at the bottom of the substrate, and the chip area of the TROM is further saved compared to the conventional planar designs of the EEPROM and NROM (see FIG. 2);

fourthly, the TROM integrating the NOR structure and the NAND structure (see FIG. 3) enables each storage unit to be addressed rapidly and improves the addressing speed due to the tunnel current.

### BIBLIOGRAPHY

1. EEPROM cell on SOI, inventors: Reedy, et al. U.S. Pat. No. 6,690,056.

2. Method of forming NROM, inventors: Sung, et al. U.S. Pat. No. 6,458,661.

3. Investigation of a novel tunneling transistor by MEDICI simulation. P.-F. Wang, Th. Nirschl, D. Schmitt-Landsiedel, W. Hansch, SISPAD 2004, Munich, Germany, 2-4 Sep. 2004.

4. Read operation scheme for a high-density, low voltage, and superior reliability nand flash memory device, Inventors: Fang, U.S. Pat. No. 6,175,522.

5. Method of channel hot electron programming for short channel NOR flash arrays, Inventors: Fastow, et al. U.S. Pat. No. 6,510,085.

6. Using hot carrier injection to control over-programming in a non-volatile memory cell having an oxide-nitride-oxide (ONO) structure, Inventors: Derhacobian, et al. U.S. Pat. No. 6,519,182.

What is claimed is:

1. A self-aligned vertical nonvolatile semiconductor memory device, characterized in that, including:
a semiconductor substrate (107);
a drain region of a first doping type (108);
two source regions of a second doping type (101a, 101b); a channel region (106) between the two source regions;
a stacked gate used to capture electrons, of which the structure includes a first dielectric (104), a second dielectric (103), a third dielectric (102) and a metal gate (105) in turn;
wherein, the drain region, the two source regions and the stacked gate form two tunneling field effect transistors (TFET) sharing one gate and one drain; in addition, the drain region current of each TFET is affected by the quantity and distribution of the charges in the stacked gate used to capture electrons; the drain region is buried in the semiconductor substrate, the two source regions above the drain region are separated from the drain region through a channel and separated from each other by a doping region of the first doping type.

2. The semiconductor memory device according to claim 1, characterized in that the substrate (107) is an intrinsic semiconductor.

3. The semiconductor memory device according to claim 1, characterized in that the substrate (107) is lightly doped.

4. The semiconductor memory device according to claim 1, characterized in that, the semiconductor substrate (107) is a part of a silicon wafer; or a part of a silicon-germanium wafer or a stress silicon wafer.

5. A TROM memory string composed of n semiconductor memory devices according to claim 1.

6. An n×n TROM memory array composed of n TROM memory strings according to claim 5.
